(19) United States
(12) Patent Application Publication
(10) Pub. No.: US 2007/0109888 A1
(43) Pub. Date: May 17, 2007

(54) Integrated circuit with test circuit

(76) Inventor: Ronald Baker, Raleigh, NC (US)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/273,059

(22) Filed: Nov. 14, 2005

(51) Int. Cl. G11C 29/00

(52) U.S. Cl. 365/201

(57) ABSTRACT

An integrated circuit including an input/output pad, an intergrated circuit, and a test circuit. The input/output pad is configured to receive first output signals of another integrated circuit that are based on input signals. The internal circuit is configured to receive the input signals and provide second output signals based on the input signals. The test circuit is configured to receive the first output signals and the second output signals, wherein the test circuit includes a comparator, a first switch, and second switch. The comparator is configured to compare the first output signals and the second output signals and provide comparison results. The first switch is configured to route the second output signals to one of an input of the comparator and the input/output pad. The second switch is configured to route the first output signals to another input of the comparator.

### BACKGROUND

Typically, a computer system includes a number of integrated circuits that communicate with one another to perform system applications. Often, the computer system includes a controller, such as a micro-processor, and one or more memory chips, such as random access memory (RAM) chips. The RAM can be any suitable type of RAM, such as dynamic RAM (DRAM), double data rate synchronous DRAM (DDR-SDRAM), graphics DDR-SDRAM (GDDR-SDRAM), reduced latency DRAM (RLDRAM), pseudo static RAM (PSRAM), and low power DDR-SDRAM (LPDDR-SDRAM).

The memory chips or components are tested after fabrication to ensure that the memory components operate properly. A typical memory test includes writing data to the memory component and reading the data back from the memory component. The data written to the memory component is compared to the data read from the memory component. If the data written to the memory component matches the data read from the memory component, the memory component is a functioning memory component. If the data written to the memory component does not match the data read from the memory component, the memory component is a defective memory component.

Memory testers have a limited number of resources, such as drivers, comparators, and power supplies, available to test memory components. The fewer resources used to test each memory component, the greater the number of memory components that can be tested simultaneously by the memory tester. Some resource limitations of memory testers include the number of driver circuits used to send inputs to the memory component and the number of driver/comparator circuits used to write data to the memory component and judge the output of the memory component.

Test methods often use a group of driver pins and one or more driver/comparators to test a memory component. Typically, memory testers use the group of driver pins to drive two or more memory components in parallel and separate driver/comparators for each memory component. Using separate driver/comparator pins for each memory component severely limits the total number of memory components that can be simultaneously tested. Therefore, in typical test systems the number of memory components that can be tested in parallel is limited by the number of available driver/comparator pins.

For these and other reasons there is a need for the present invention.

### SUMMARY

One aspect of the present invention provides an integrated circuit including an input/output pad, an internal circuit, and a test circuit. The input/output pad is configured to receive first output signals of another integrated circuit that are based on input signals. The internal circuit is configured to receive the input signals and provide second output signals based on the input signals. The test circuit is configured to receive the first output signals and the second output signals, wherein the test circuit includes a comparator, a first switch, and second switch. The comparator is configured to compare the first output signals and the second output signals and provide comparison results. The first switch is configured to route the second output signals to one of an input of the comparator and the input/output pad. The second switch is configured to route the first output signals to another input of the comparator.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of memory components configured to be tested via a test system according to the present invention.

FIG. 2 is a diagram illustrating one embodiment of a test circuit.

FIG. 3 is a diagram illustrating the test circuit of FIG. 2 in normal mode.

FIG. 4 is a diagram illustrating the test circuit of FIG. 2 in test mode.

FIG. 5 is a diagram illustrating one embodiment of an accumulator circuit.

FIG. 6 is a diagram illustrating one embodiment of a result switch indicating that no mismatch was detected.

FIG. 7 is a diagram illustrating one embodiment of a result switch indicating that a mismatch was detected.

FIG. 8 is a flow chart diagram illustrating an example operation of the accumulator circuit of FIG. 5.

FIG. 9 is a flow chart diagram illustrating an example of reading test results of memory components in a test system.

FIG. 10 is a block diagram illustrating another embodiment of memory components configured to be tested via a test system according to the present invention.

FIG. 11 is a diagram illustrating another embodiment of a test circuit.

FIG. 12 is a diagram illustrating the test circuit of FIG. 11 in normal mode.

FIG. 13 is a diagram illustrating the test circuit of FIG. 11 in test mode.

FIG. 14 is a diagram illustrating the test circuit of FIG. 11 in test result output mode.

FIG. 15 is a flow chart diagram illustrating an example of reading test results from memory components via a test system.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

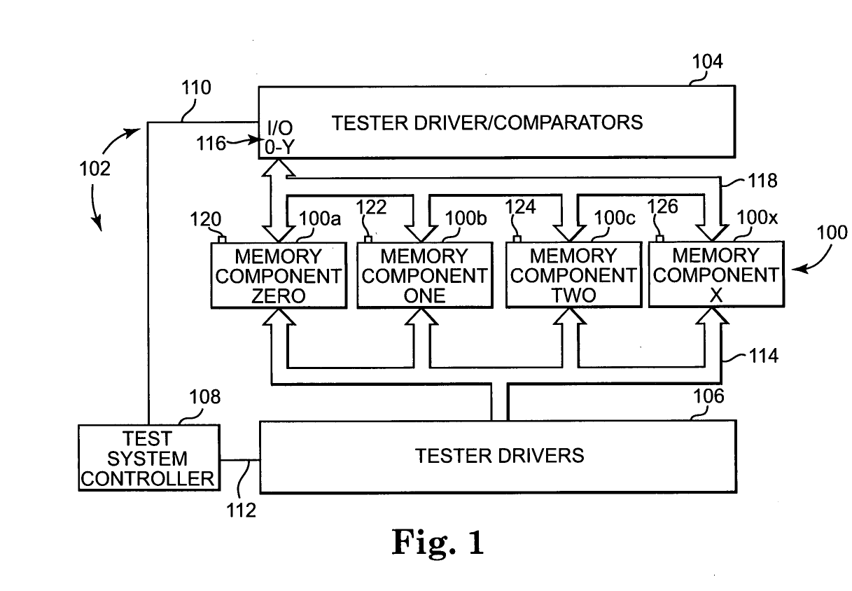

FIG. 1 is a block diagram illustrating one embodiment of memory components 100 configured to be tested via a test system 102 according to the present invention. Memory components 100 and test system 102 are configured to increase the number of memory components 100 that can be tested in parallel via test system 102. The number of memory components 100 tested in parallel is increased by reducing the number of test system driver/comparators used to test at least some of the memory components 100. In other embodiments, the memory components 100 can be any suitable integrated circuit components.

Each of the memory components 100 includes one or more test circuits that can be used to reduce the number of test system driver/comparators or input/output drivers needed to test the memory component. To test memory components 100, one of the memory components 100 is designated a master component and the other memory components 100 are designated as slave components. The master component provides output signals to the slave components and each of the slave components judges its own output signals against the master component output signals via the internal test circuits.

Each of the memory components 100 includes a normal mode of operation and a test mode of operation. To test memory components 100, the master component is put into normal mode and the slave components are put into test mode. Test system 102 compares output signals from the master component against expected results to obtain a test result for the master component. Each of the slave components compares its own output signals against the master component output signals to obtain a test result that is read via test system 102.

Test system 102 is configured to test a suitable number of memory components 100 including memory component zero 100a, memory component one 100b, memory component two 100c, and so on, up to and including memory component X 100x. Memory component zero 100a is the master component and memory components 100b-100x are slave components. In other embodiments, any suitable one of the memory components 100a-100x can be designated the master component and the other memory components 100a-100x can be designated as slave components.

Test system 102 includes tester driver/comparators 104, tester drivers 106, and a test system controller 108. Tester driver/comparators 104 are electrically coupled to test system controller 108 via control communications path 110. Test system controller 108 is electrically coupled to tester drivers 106 via driver control communications path 112. Also, tester drivers 106 are electrically coupled to inputs of memory components 100a-100x via driver communications path 114.

Tester driver/comparators 104 include input/output (I/O) pins or pads 0-Y at 116 that are electrically coupled to master memory component zero 100a and slave memory components 100b-100x via driver/comparator communications path 118. In one embodiment, driver/comparator communications path 118 includes bi-directional buffers between I/O pins 0-Y at 116 and master memory component zero 100a. In one embodiment, driver/comparator communications path 118 includes buffers between I/O pins 0-Y at 116 and slave memory components 100b-100x and between master memory component zero 100a and slave memory components 100b-100x.

Tester driver/comparators 104 drive data signals to memory components 100a-100x and receive output signals from master memory component zero 100a. Also, tester driver/comparators 104 compare the output signals from master memory component zero 100a to the data signals driven to memory components 100a-100x to determine a test result for the master memory component zero 100a. Tester drivers 106 drive signals, such as address signals, command signals, and clock signals, to memory components 100a-100x.

Test system controller 108 controls the operation of test system 102 including the timing of data and control signals through tester drivers 106 and tester driver/comparators 104. Tester drivers 106 provide control signals to memory components 100a-100x to put memory component zero 100a into normal mode and the other memory components 100b-100x into test mode. Also, tester drivers 106 provide address signals, command signals, and clock signals to write test data to memory components 100a-100x and to read test data output signals from memory components 100a-100x. Tester driver/comparators 104 write test data to memory components 100a-100x and read test data output signals from master memory component zero 100a. Also, tester driver/comparators 104 compare the test data written to memory components 100a-100x to the test data read from master memory component zero 100a to obtain a test result for master memory component zero 100a.

Each of the memory components 100a-100x includes a power pin coupled to test system 102. Memory component zero 100a includes power pin 120, memory component one 100b includes power pin 122, memory component two 100c includes power pin 124, and so on, up to and including memory component X 100x that includes power pin 126. Each of the slave memory components 100b-100x internally compares its output signals to output signals from master memory component zero 100a to obtain a test result. Test system controller 108 controls test system 102 to provide power to each of the slave memory components 100b-100x separately to read the test result from the powered slave memory component 100b-100x. In one embodiment, each of the memory components 100a-100x is a RAM circuit, such as a DRAM, DDR-SDRAM, GDDR-SDRAM, RLDRAM, PSRAM, LPDDR-SDRAM, or another suitable type of RAM.

In operation, test system controller 108 controls tester drivers 106 to program memory component zero 100a to operate in normal mode. Also, test system controller 108 controls tester drivers 106 to program memory components 100b-100x to operate in test mode. Test system controller 108 controls tester drivers 106 and tester driver/comparators 104 to write test data to master memory component zero 100a and slave memory components 100b-100x.

After the test data has been written to memory components 100a-100x, test system controller 108 controls tester driver/comparators 104 and tester drivers 106 to read the data stored in memory components 100a-100x. The test data read from master memory component zero 100a is passed to I/O pins 0-Y at 116 and to slave memory components 100b-100x via driver/comparator communications path 118. Tester driver/comparators 104 compare the test data that was written to memory components 100a-100x to the test data read from master memory component zero 100a to obtain a test result. If the test data written to memory components 100a-100x matches the test data read from master memory component zero 100a, master memory component zero 100a passes the test indicating a functional memory component. If the test data written to memory components 100a-100x does not match the data read from master memory component zero 100a, then master memory component zero 100a fails the test indicating a defective memory component and all slave memory components 100b-100x are failed and can be retested.

Each of the slave memory components 100b-100x internally compares its output signals to output signals from master memory component zero 100a to obtain a test result. If the master memory component zero 100a passes and the test data received from master memory component zero 100a matches the test data from the slave memory component 100b-100x, the slave memory component 100b-100x passes the test indicating a functional memory component. If the test data received from a passing master memory component zero 100a does not match the test data of the slave memory component 100b-100x, the slave memory component 100b-100x fails the test indicating a defective memory component. Test system controller 108 controls test system 102 to provide power to each of the slave memory components 100b-100x separately to read the test result from the powered slave memory component 100b-100x.

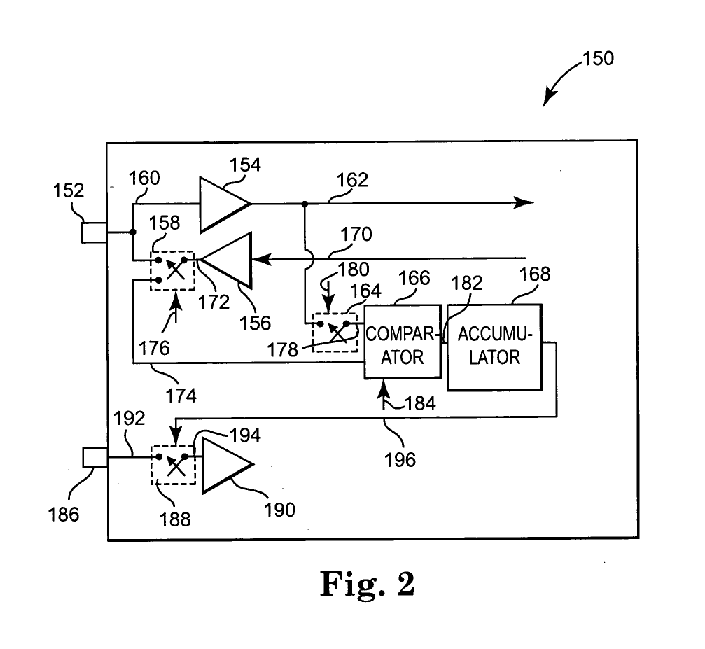

FIG. 2 is a diagram illustrating one embodiment of a test circuit 150. Each of the memory components 100 includes at least one test circuit similar to test circuit 150. In one embodiment, each of the memory components 100 includes test circuits similar to test circuit 150, wherein each of the test circuits is coupled to receive signals via one of the I/O pins 0-Y at 116, and each of the test circuits in a slave component is coupled to receive output signals from a test circuit in the master component and each of the I/O pins 0-Y at 116 is coupled to receive the output signals from the test circuit in the master component. In other embodiments, any suitable integrated circuit component may include at least one test circuit 150.

Test circuit 150 is configured to operate in the normal mode or the test mode. In the normal mode, test circuit 150 receives data signals read from the internal memory cells of the memory component 100 that includes test circuit 150. Test circuit 150 directs the received data signals to an I/O pin or pad to provide data output signals. In test mode, test circuit 150 receives output signals from a master component and data signals from the internal memory cells and compares these signals to obtain a comparison test result. The comparison test results are accumulated to obtain a final test result that controls a switch. The state of the switch is read to indicate whether the memory component 100 that includes test circuit 150 passed or failed the test. In normal mode and in test mode, signals received via the I/O pin are directed to internal circuitry of the memory component 100 that includes test circuit 150.

Test circuit 150 includes I/O pin 152, an I/O receiver 154, an I/O driver 156, and an I/O switch 158. I/O pad 152 is electrically coupled to the input of I/O receiver 154 and one output of I/O switch 158 via I/O communications path 160. The output of I/O receiver 154 is electrically coupled to internal circuitry of the memory component 100 that includes test circuit 150 via receiver communications path 162. I/O pad 152 is electrically coupled to one of the I/O pins 0-Y at 116 and to at least one other memory component 100, such as a master component or a slave component. I/O pad 152 receives signals and I/O receiver 154 provides the received signals to the internal circuitry in the memory component 100 that includes test circuit 150.

Test circuit 150 includes a comparator input switch 164, a comparator circuit 166, and an accumulator circuit 168. The input of I/O driver 156 is electrically coupled to internal memory cells in the memory component 100 that includes test circuit 150 via driver communications path 170. The output of I/O driver 156 is electrically coupled to the input of I/O switch 158 via switch communications path 172 and the other output of I/O switch 158 is electrically coupled to one input of comparator circuit 166 via switch output communications path 174. I/O driver 156 receives data signals from the internal memory cells and I/O switch 158 is controlled at 176 via a test mode control circuit (not shown) to direct the received internal data signals to I/O pin 152 or comparator circuit 166. The test mode control circuit is part of memory component 100 that includes test circuit 150. In other embodiments, the test mode control circuit is part of an external device.

The input of comparator input switch 164 is electrically coupled to the output of I/O receiver 154 via receiver communications path 162 and the output of comparator input switch 164 is electrically coupled to the other input of comparator circuit 166 via input communications path 178. Comparator input switch 164 is controlled at 180 via the test mode control circuit to be open or to direct signals provided via I/O receiver 154 to comparator circuit 166.

The output of comparator circuit 166 is electrically coupled to the input of accumulator circuit 168 via comparison communications path 182. Comparator circuit 166 receives a comparison trigger at 184 via a circuit, such as the test mode control circuit, to trigger a comparison of the signals received at its inputs. Comparator circuit 166 provides comparison test results to accumulator circuit 168 via comparison communications path 182. Accumulator circuit 168 receives the comparison test results and provides an indication, such as a logic high output signal, to indicate at least one non-matching or failing comparison test result.

Test circuit 150 includes a result pin 186, a result switch 188, and a result input receiver 190. Result pin 186 is electrically coupled to one side of result switch 188 via result communications path 192. The other side of result switch 188 is electrically coupled to the input of result input receiver 190 via result receiver communications path 194. The output of accumulator circuit 168 is electrically coupled to the control input of result switch 188 via control communications path 196. The output signal indication from accumulator circuit 168 controls the state of result switch 188. In one embodiment, result switch 188 defaults to a closed state to provide the impedance of the result input receiver 190 at result pad 186, and a logic high output signal that indicates at least one non-matching or failing comparison test result opens result switch 188 to provide an open high impedance at result pad 186. Test system 102 reads the open/closed state of result switch 188 via an opens test, such as an open current test.

Test system 102 and the test mode control circuit in each of the memory components 100 controls the state of each I/O switch 158 and each comparator input switch 164 to put each of the test circuits 150 in normal mode or test mode. Test circuits 150 in a master component, such as master memory component zero 100a, are put into normal mode by closing I/O switch 158 to provide the output from I/O driver 156 to I/O pin 152 and by opening comparator input switch 164. Result switch 188 defaults to a closed state to provide the impedance of result input receiver 190 at result pad 186. Test circuits 150 in each of the slave components, such as slave components 100b-100x, are put into slave mode by closing I/O switch 158 to provide the output from I/O driver 156 to the input of comparator circuit 166 and by closing comparator input switch 164 to provide the output from I/O receiver 154 to the other input of comparator circuit 166. Result switch 188 is controlled by the test result output signal from accumulator circuit 168.

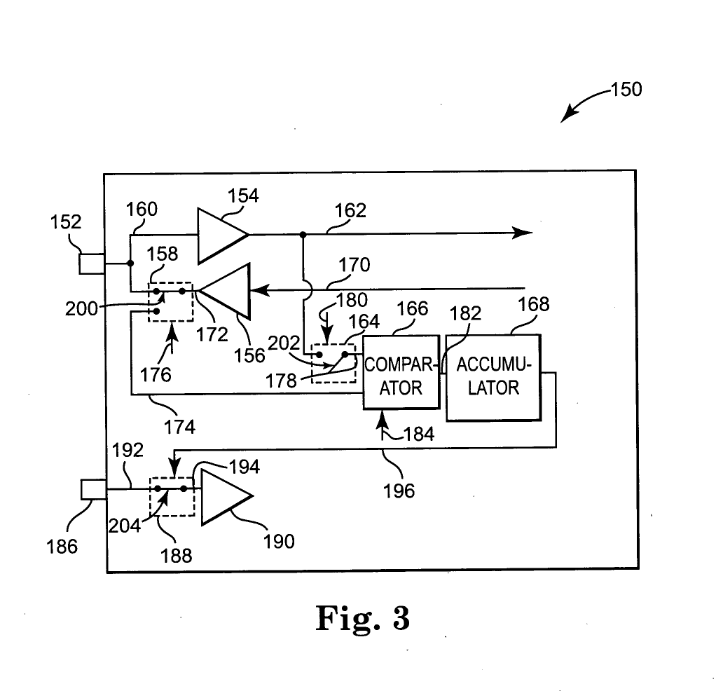

FIG. 3 is a diagram illustrating test circuit 150 in normal mode. In test system 102, memory component zero 100a is designated a master component and put into normal mode. Memory component zero 100a receives control signals via tester drivers 106 to put test circuit 150 into normal mode. I/O switch 158 is switched at 200 to provide the output from I/O driver 156 to I/O pin 152. Also, comparator input switch 164 is opened at 202 to reduce leakage current. In addition, result switch 188 defaults to a closed state at 204 to provide the impedance of result input receiver 190 at result pad 186.

In a write operation, I/O pin 152 receives input signals and I/O receiver 154 provides the input signals to the internal circuitry of memory component zero 100a. The input signals can be data signals that are written into memory component zero 100a as part of a test operation. Comparator input switch 164 is open and the input signals are not provided to comparator circuit 166.

In a read operation, I/O driver 156 receives internal data signals from the internal memory cells of memory component zero 100a. I/O driver 156 provides the received data signals to I/O pin 152. Also, as a master component, memory component zero 100a provides the received data signals via I/O driver 156 to one of the I/O pins 0-Y at 116 and slave memory components 100b-100x.

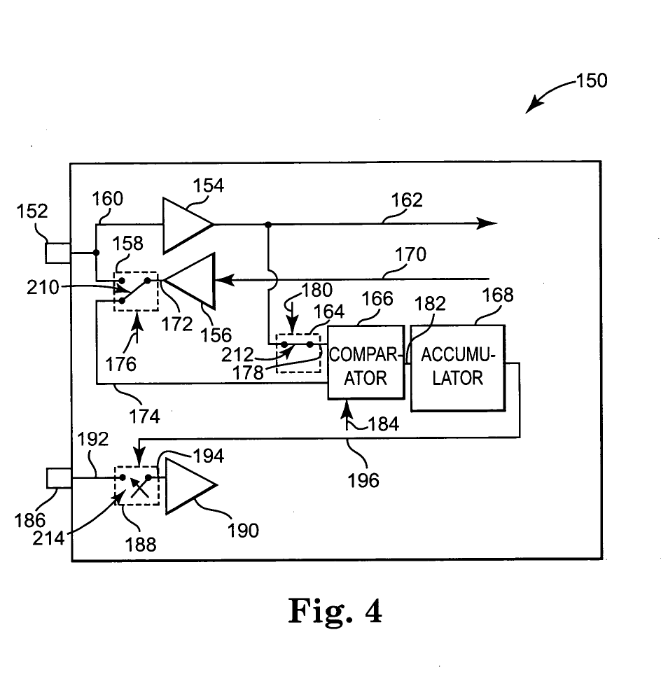

FIG. 4 is a diagram illustrating test circuit 150 in test mode. In test system 102, memory components 100b-100x are designated as slave components and put into test mode. Each of the memory components 100a-100x receives control signals via tester drivers 106 to put test circuit 150 into test mode. I/O switch 158 is switched at 210 to provide the output from I/O driver 156 to the input of comparator circuit 166. Also, comparator input switch 164 is closed at 212 to provide the output from I/O receiver 154 to the other input of comparator circuit 166. In addition, result switch 188 is controlled via the test result output signal from accumulator circuit 168.

In a write operation, I/O pin 152 receives input signals and I/O receiver 154 provides the input signals to the internal circuitry of a memory component 100b-100x that includes test circuit 150. The input signals can be data signals that are written into memory component 100b-100x as part of a test operation. Comparator input switch 164 is closed and the input signals are provided to comparator circuit 166, however, the comparison trigger at 184 is not activated to trigger a comparison via comparator circuit 166.

In a read operation, I/O driver 156 receives internal data signals from the internal memory cells of memory component 100b-100x. I/O driver 156 provides the received data signals to the input of comparator circuit 166. Also, I/O pin 152 receives data output signals from the master memory component zero 100a and I/O receiver 154 provides the received data output signals to the other input of comparator circuit 166 via comparator input switch 164. The comparison trigger at 184 is activated and comparator circuit 166 compares the inputs and provides a comparison test result to accumulator circuit 168. If the comparison test result indicates a passing memory component, the result switch 188 is closed at 214 to provide the impedance of result input receiver 190 at result pad 186. If any of the comparison test results indicate a failing memory component, the result switch 188 is opened at 214 to provide an open high impedance at result pin 186. Test system 102 provides power to each of the slave memory components 100b-100x separately to read the test result from the powered slave memory component 100b-100x via an opens test on result pin 186.

FIG. 5 is a diagram illustrating one embodiment of an accumulator circuit 168. Accumulator circuit 168 includes a latch circuit 220 and a driver circuit 222. The input of latch circuit 220 is electrically coupled to comparator circuit 166 via communications path 182 and the output of latch circuit 220 is electrically coupled to the input of driver circuit 222 via latch communications path 224. The output of driver circuit 222 is electrically coupled to the control input of result switch 188 via communications path 196.

In operation, latch circuit 220 is reset to provide a deactivated output signal, such as a low logic level, at the output of latch circuit 220. Driver circuit 222 receives the deactivated output signal and provides an inactive output signal to the control input of result switch 188. The inactive output signal does not switch the result switch 188. In one embodiment, result switch 188 defaults to a closed position and the inactive output signal does not switch the result switch 188 to an open.

Comparator circuit 166 provides comparison test results to the input of latch circuit 220. If one of the comparison test results indicates a mismatch or failing test result, latch circuit 220 latches in an activated output signal, such as a high logic level, at the output of latch circuit 220. Driver circuit 222 receives the activated output signal and provides an active output signal to the control input of result switch 188. The active output signal switches the result switch 188. In one embodiment, result switch 188 defaults to a closed position and the active output signal switches the result switch 188 to an open position.

If none of the comparison test results indicate a mismatch, that is if all the comparison test results indicate a match, latch circuit 220 continues to provide the deactivated output signal, such as a low logic level, at the output of latch circuit 220. Also, driver circuit 222 continues to receive the deactivated output signal and provides an inactive output signal to the control input of result switch 188, which does not switch the result switch 188.

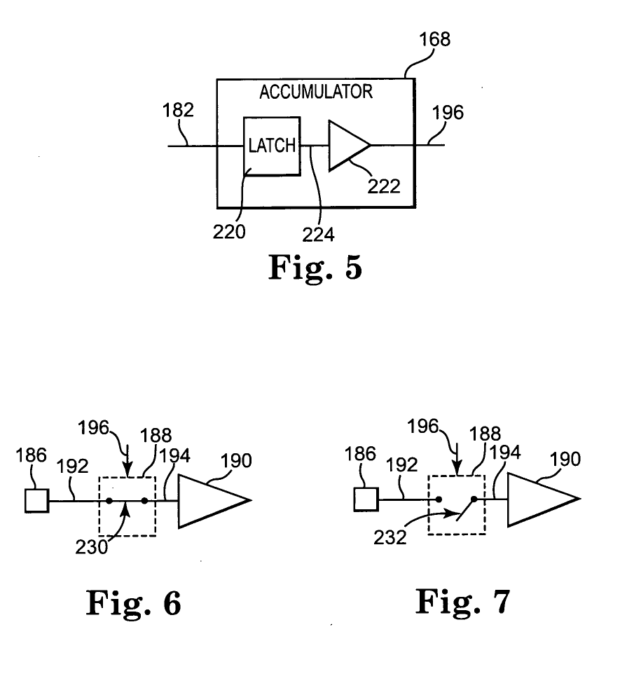

FIG. 6 is a diagram illustrating one embodiment of result switch 188 indicating that no mismatch was detected. Result pin 186 is electrically coupled to one side of result switch 188 via result communications path 192. The other side of result switch 188 is electrically coupled to the input of result input receiver 190 via result receiver communications path 194. The output of result input receiver 190 is electrically coupled to any suitable internal circuitry in the memory component that includes result switch 188. The output of accumulator circuit 168 is electrically coupled to the control input of result switch 188 via control communications path 196. The output signal from accumulator circuit 168 controls the state of result switch 188.

In this embodiment, result switch 188 defaults to a closed state at 230 to provide the impedance of the result input receiver 190 at result pad 186. If none of the comparison test results indicate a mismatch, accumulator circuit 168 continues to provide an inactive output signal to the control input of result switch 188. Result switch remains closed at 230 and test system 102 reads the closed state of result switch 188 via an opens test. The opens test indicates result pin 186 is not open, but connected to result input receiver 190.

FIG. 7 is a diagram illustrating one embodiment of result switch 188 indicating that a mismatch was detected. Result pin 186 is electrically coupled to one side of result switch 188 via result communications path 192. The other side of result switch 188 is electrically coupled to the input of result input receiver 190 via result receiver communications path 194. The output of result input receiver 190 is electrically coupled to any suitable internal circuitry in the memory component that includes result switch 188. The output of accumulator circuit 168 is electrically coupled to the control input of result switch 188 via control communications path 196. The output signal from accumulator circuit 168 controls the state of result switch 188.

In this embodiment, result switch 188 defaults to a closed state to provide the impedance of the result input receiver 190 at result pad 186. If at least one of the comparison test results indicates a mismatch, accumulator circuit 168 provides an active output signal to the control input of result switch 188. Result switch 188 opens at 232 and test system 102 reads the open state of result switch 188 via an opens test. The opens test indicates result pin 186 is in a high impedance open state.

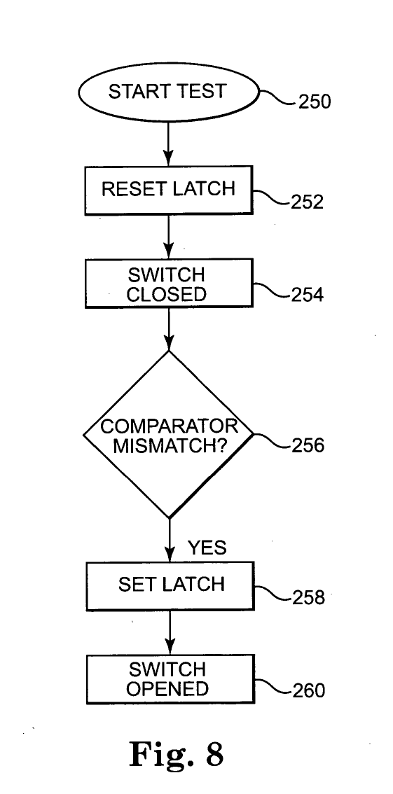

FIG. 8 is a flowchart diagram illustrating an example operation of accumulator circuit 168 of FIG. 5. A test operation begins at 250 and latch circuit 220 is reset at 252 to provide a deactivated output signal, such as a low logic level, at the output of latch circuit 220. Driver circuit 222 receives the deactivated output signal and provides an inactive output signal to the control input of result switch 188. The inactive output signal does not open result switch 188 and result switch 188 defaults to the closed position at 254.

Comparator circuit 166 provides comparison test results at 256 to the input of latch circuit 220. If none of the comparison test results indicate a mismatch, that is if all the comparison test results indicate a match, latch circuit 220 continues to provide the deactivated output signal, such as a low logic level, at the output of latch circuit 220. Also, driver circuit 222 continues to receive the deactivated output signal and provide an inactive output signal to the control input of result switch 188.

If one of the comparison test results indicates a mismatch or failing test result, latch circuit 220 is set at 258 to provide an activated output signal, such as a high logic level. Driver circuit 222 receives the activated output signal and provides an active output signal to the control input of result switch 188. The active output signal switches the result switch 188 to an open position at 260. Test system reads the open state of result switch 188 to obtain the failed test result.

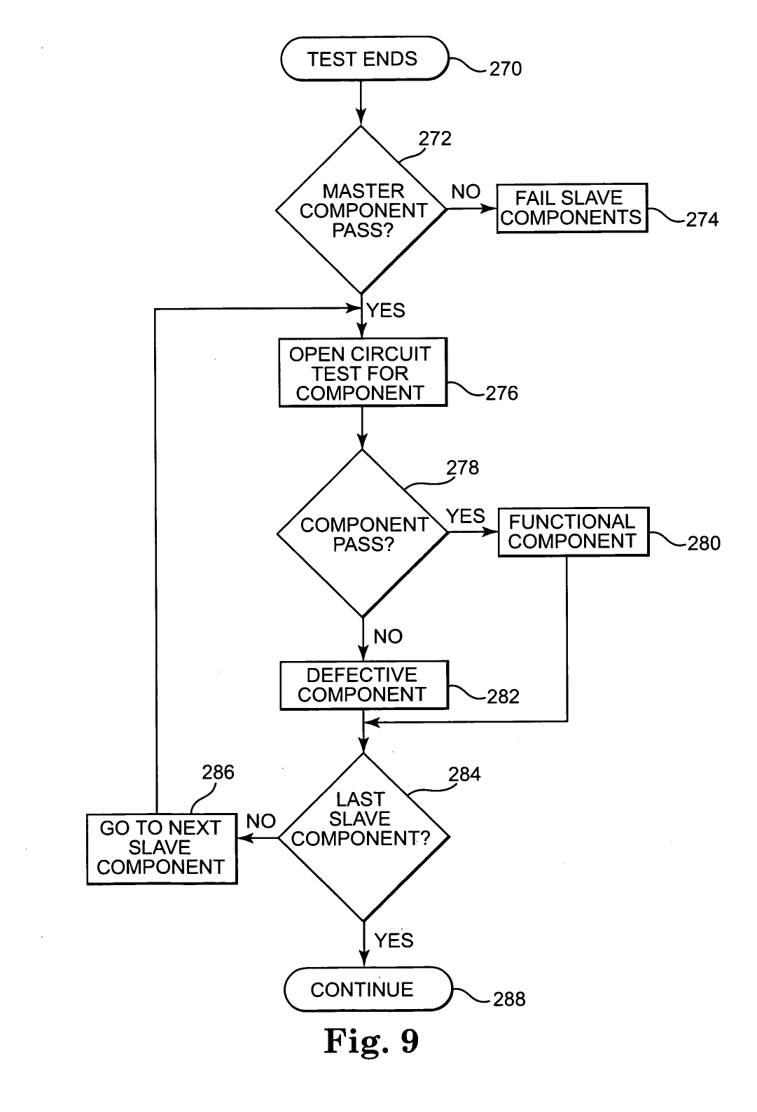

FIG. 9 is a flowchart diagram illustrating an example of reading test results of memory components 100a-100x in test system 102. A test operation, such as a functional test operation, ends at 270. If master memory component zero 100a fails at 272, all of the slave memory components 100b-100x are failed at 274. The slave memory components 100b-100x can be retested using a different master component. If master memory component zero 100a passes at 272, an open circuit test is performed on each of the slave memory components 100b-100x to obtain the pass/fail status of each of the slave memory components 100b-100x.

At 276, one of the slave memory components 100b-100x is powered up and the other components, including master memory component 100a, are powered down. If the powered slave component passes at 278, i.e., if the powered slave component's result switch 188 is closed to provide the input resistance of result input receiver 190, the powered slave component is identified as a functional component at 280 via test system 102. If the powered slave component fails at 278, i.e. if the powered slave component's result switch 188 is open to provide a high impedance value, the powered slave component is identified as a defective component at 282 via test system 102.

If other slave memory components 100b-100x remain to be tested for open circuits at 284, test system 102 selects the next one of the slave memory components 100b-100x at 286. The selected one of the slave memory components 100b-100x is powered up at 276 and the other components, including master memory component 100a, are powered down and the process repeats. After the last of the slave memory components 100b-100x is identified as a functional or defective component, the process continues at 288 until completed.

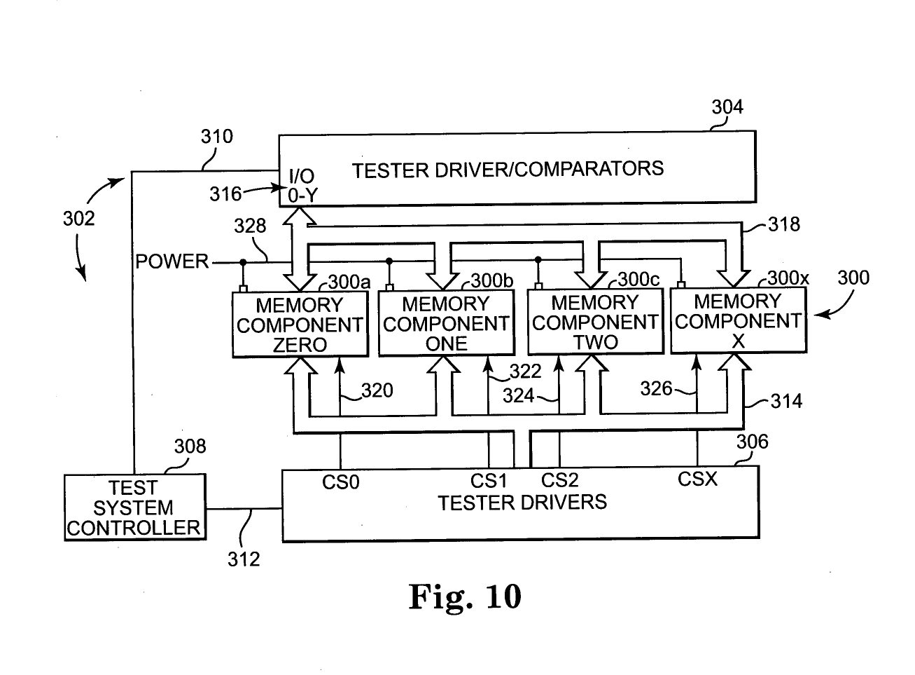

FIG. 10 is a block diagram illustrating one embodiment of memory components 300 configured to be tested via a test system 302 according to the present invention. Test system 302 is similar to test system 102 and memory components 300 are similar to memory components 100, with the exceptions that all memory components 300 receive the same power signal and each of the memory components 300 is individually addressed via a chip select signal. Also, each of the memory components 300 includes one or more test circuits that provide the test result at an I/O pin.

Memory components 300 and test system 302 are configured to increase the number of memory components 300 that can be tested in parallel via test system 302. The number of memory components 300 tested in parallel is increased by reducing the number of test system driver/comparators used to test at least some of the memory components 300. In other embodiments, the memory components 300 can be any suitable integrated circuit components.

Each of the memory components 300 includes one or more test circuits that can be used to reduce the number of test system driver/comparators or input/output drivers needed to test the memory component. To test memory components 300, one of the memory components 300 is designated a master component and the other memory components 300 are designated as slave components. The master component provides output signals to the slave components and each of the slave components judges its own output signals against the master component output signals via the internal test circuits.

Each of the memory components 300 includes a normal mode of operation and a test mode of operation. To test memory components 300, the master component is put into normal mode and the slave components are put into test mode. Test system 302 compares output signals from the master component against expected results to obtain a test result for the master component. Each of the slave components compares its own output signals against the master component output signals to obtain a test result that is read via test system 302.

Test system 302 is configured to test a suitable number of memory components 300 including memory component zero 300a, memory component one 300b, memory component two 300c, and so on, up to and including memory component X 300x. Memory component zero 300a is the master component and memory components 300b-300x are slave components. In other embodiments, any suitable one of the memory components 300a-300x can be designated the master component and the other memory components 300a-300x can be designated as slave components.

Test system 302 includes tester driver/comparators 304, tester drivers 306, and a test system controller 308. Tester driver/comparators 304 are electrically coupled to test system controller 308 via control communications path 310. Also, test system controller 308 is electrically coupled to tester drivers 306 via driver control communications path 312.

Tester drivers 306 are electrically coupled to inputs of memory components 300a-300x via driver communications path 314. Also, tester drivers 306 are electrically coupled to each of the memory components 300a-300x to provide chip select signals CS0-CSX. One of the tester drivers 306 is electrically coupled to provide chip select signal CS0 to memory component zero 300a via chip select zero communications path 320. Another of the tester drivers 306 is electrically coupled to provide chip select signal CS1 to memory component one 300b via chip select one communications path 322. Another of the tester drivers 306 is electrically coupled to provide chip select signal CS2 to memory component two 300c via chip select two communications path 324, and so on, up to and including another of the tester drivers 306 being electrically coupled to provide chip select signal CSX to memory component X 300x via chip select X communications path 326. In addition each of the memory components 300a-300x is electrically coupled to power path 328 to receive power signal POWER.

Tester driver/comparators 304 include I/O pins 0-Y at 316 that are electrically coupled to master memory component zero 300a and slave memory components 300b-300x via driver/comparator communications path 318. In one embodiment, driver/comparator communications path 318 includes bi-directional buffers between I/O pins 0-Y at 316 and master memory component zero 300a. In one embodiment, driver/comparator communications path 318 includes buffers between I/O pins 0-Y at 316 and slave memory components 300b-300x and between master memory component zero 300a and slave memory components 300b-300x.

Tester driver/comparators 304 drive data signals to memory components 300a-300x and receive output signals from master memory component zero 300a. Also, tester driver/comparators 304 compare the output signals from master memory component zero 300a to the data signals driven to memory components 300a-300x to determine a test result for the master memory component zero 300a. Tester drivers 306 drive signals, such as address signals, command signals, clock signals and chip select signals CS0-CSX, to memory components 300a-300x.

Test system controller 308 controls the operation of test system 302 including the timing of data and control signals through tester drivers 306 and tester driver/comparators 304. Tester drivers 306 provide control signals to memory components 300a-300x to put memory component zero 300a into normal mode and the other memory components 300b-300x into test mode. Also, tester drivers 306 provide address signals, command signals, and clock signals to write test data to memory components 300a-300x and to read test data output signals from memory components 300a-300x. Tester driver/comparators 304 write test data to memory components 300a-300x and read test data output signals from master memory component zero 300a. Also, tester driver/comparators 304 compare the test data written to memory components 300a-300x to the test data read from master memory component zero 300a to obtain a test result for master memory component zero 300a.

Each of the slave memory components 300b-300x internally compares its output signals to output signals from master memory component zero 300a to obtain a test result. Test system controller 308 controls test system 302 to select each of the slave memory components 300b-300x separately via chip select signals CS0-CSX and to read the test result from the selected slave memory component 300b-300x. In one embodiment, each of the memory components 300a-300x is a RAM circuit, such as a DRAM, DDR-SDRAM, GDDR-SDRAM, RLDRAM, PSRAM, LPDDR-SDRAM, or another suitable type of RAM.

In operation, test system controller 308 controls tester drivers 306 to program memory component zero 300a to operate in normal mode. Also, test system controller 308 controls tester drivers 306 to program memory components 300b-300x to operate in test mode. Test system controller 308 controls tester drivers 306 and tester driver/comparators 304 to write test data to master memory component zero 300a and slave memory components 300b-300x.

After the test data has been written to memory components 300a-300x, test system controller 308 controls tester driver/comparators 304 and tester drivers 306 to read the data stored in memory components 300a-300x. The test data read from master memory component zero 300a is passed to I/O pins 0-Y at 316 and to slave memory components 300b-300x via driver/comparator communications path 318. Tester driver/comparators 304 compare the test data that was written to memory components 300a-300x to the test data read from master memory component zero 300a to obtain a test result. If the test data written to memory components 300a-300x matches the test data read from master memory component zero 300a, master memory component zero 300a passes the test indicating a functional memory component. If the test data written to memory components 300a-300x does not match the data read from master memory component zero 300a, then master memory component zero 300a fails the test indicating a defective memory component and all slave memory components 300b-300x are failed and can be retested.

Each of the slave memory components 300b-300x internally compares its output signals to output signals from master memory component zero 300a to obtain a test result. If the master memory component zero 300a passes and the test data received from master memory component zero 300a matches the test data from the slave memory component 300b-300x, the slave memory component 300b-300x passes the test indicating a functional memory component. If the test data received from a passing master memory component zero 300a does not match the test data of the slave memory component 300b-300x, the slave memory component 300b-300x fails the test indicating a defective memory component. Test system controller 308 controls test system 302 to select each of the slave memory components 300b-300x separately via chip select signals CS0-CSX to read the test result from the selected slave memory component 300b-300x.

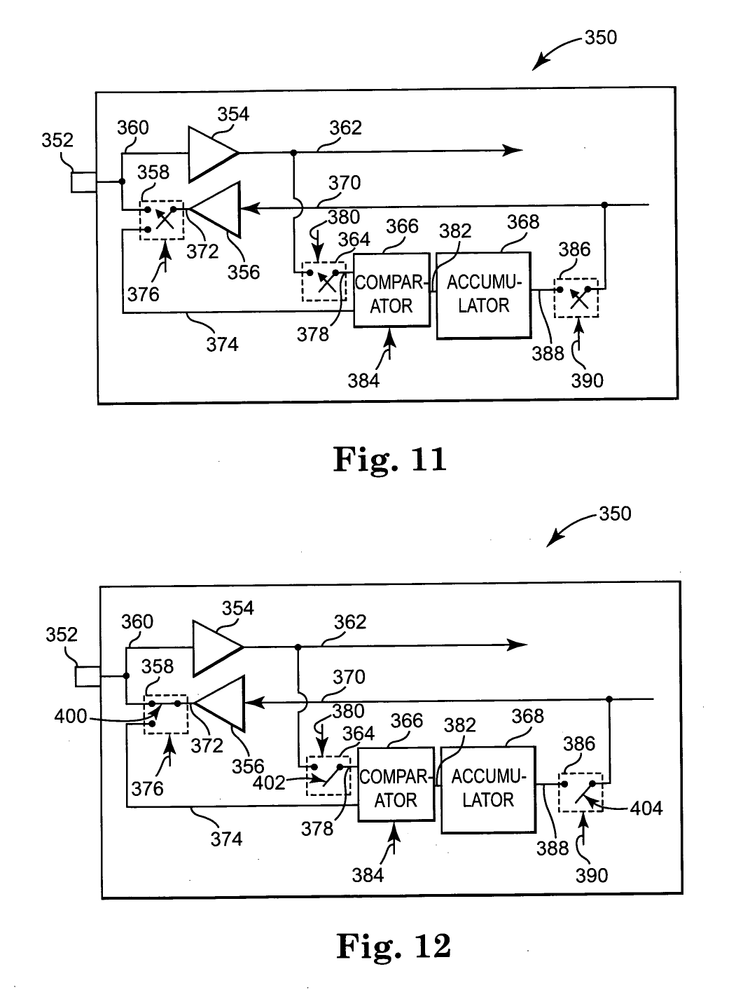

FIG. 11 is a diagram illustrating one embodiment of a test circuit 350. Each of the memory components 300 includes at least one test circuit similar to test circuit 350. In one embodiment, each of the memory components 300 includes test circuits similar to test circuit 350, wherein each of the test circuits 350 is coupled to receive signals via one of the I/O pins 0-Y at 316. Also, each of the test circuits 350 in the master component is coupled to provide output signals to test circuits 350 in the slave components and to the I/O pins 0-Y at 316. In other embodiments, any suitable integrated circuit component may include at least one test circuit 350.

Test circuit 350 is configured to operate in the normal mode or the test mode. Test circuit 350 is also configured to operate in a test result output mode. In the normal mode, test circuit 350 receives data signals read from the internal memory cells of the memory component 300 that includes test circuit 350. Test circuit 350 directs the received data signals to an I/O pin or pad to provide data output signals. In test mode, test circuit 350 receives output signals from a master component and data signals from the internal memory cells and compares these signals to obtain a comparison test result. The comparison test results are accumulated to obtain a final test result. Test circuit 350 is put into the test result output mode and test system 302 reads the final test result from the I/O pin. The final test result indicates whether the memory component 300 passed or failed the test. In normal mode and in test mode, signals received via the I/O pin are directed to internal circuitry of the memory component 300 that includes test circuit 350.

Test circuit 350 includes I/O pin 352, an I/O receiver 354, an I/O driver 356, and an I/O switch 358. I/O pad 352 is electrically coupled to the input of I/O receiver 354 and one output of I/O switch 358 via I/O communications path 360. The output of I/O receiver 354 is electrically coupled to internal circuitry of the memory component 300 that includes test circuit 350 via receiver communications path 362. I/O pad 352 is electrically coupled to one of the I/O pins 0-Y at 316 and to at least one other memory component 300, such as a master component or a slave component. I/O pad 352 receives signals and I/O receiver 354 provides the received signals to the internal circuitry in the memory component 300 that includes test circuit 350.

Test circuit 350 includes a comparator input switch 364, a comparator circuit 366, and an accumulator circuit 368. The input of I/O driver 356 is electrically coupled to internal memory cells in the memory component 300 via driver communications path 370. The output of I/O driver 356 is electrically coupled to the input of I/O switch 358 via switch communications path 372 and the other output of I/O switch 358 is electrically coupled to one input of comparator circuit 366 via switch output communications path 374. I/O driver 356 receives data signals from the internal memory cells and I/O switch 358 is controlled at 376 via a test mode control circuit (not shown) to direct the received internal data signals to I/O pin 352 or comparator circuit 366. The test mode control circuit is part of memory component 300 that includes test circuit 350. In other embodiments, the test mode control circuit is part of an external device.

The input of comparator input switch 364 is electrically coupled to the output of I/O receiver 354 via receiver communications path 362 and the output of comparator input switch 364 is electrically coupled to the other input of comparator circuit 366 via input communications path 378. Comparator input switch 364 is controlled at 380 via the test mode control circuit to be open or to direct signals provided via I/O receiver 354 to comparator circuit 366.

The output of comparator circuit 366 is electrically coupled to the input of accumulator circuit 368 via comparison communications path 382. Comparator circuit 366 receives a comparison trigger at 384 via a circuit, such as the test mode control circuit, to trigger a comparison of the signals received at its inputs. Comparator circuit 366 provides comparison test results to accumulator circuit 368 via comparison communications path 382. Accumulator circuit 368 receives the comparison test results and provides an indication, such as a logic high output signal, to indicate at least one non-matching or failing comparison test result.

Test circuit 350 includes a result switch 386. The input of result switch 386 is electrically coupled to the output of accumulator circuit 368 via result output communications path 388. The output of result switch 386 is electrically coupled to the input of I/O driver 356 via driver communications path 370. Result switch 386 is controlled at 390 via the test mode control circuit. To read the test result from accumulator circuit 368, the output signal from accumulator circuit 368 is directed to I/O driver 356 via result switch 386 and the output of I/O driver 356 is directed to I/O pin 352 via I/O switch 358. Test system 102 reads the test result output signal from I/O pin 352. In one embodiment, a logic low output signal indicates a functional passing component and a logic high output signal indicates at least one non-matching or failing comparison test result and a defective failing component.

Test system 302 and the test mode control circuit in each of the memory components 300 controls the state of each I/O switch 358, each comparator input switch 364, and each result switch 386 to put each of the test circuits 350 into one of the normal mode, the test mode, or the test result output mode. Test circuits 350 in a master component, such as master memory component zero 300a, are put into normal mode by switching I/O switch 358 to provide the output from I/O driver 356 to I/O pin 352 and by opening comparator input switch 364 and result switch 386.

Test circuits 350 in each of the slave components, such as slave components 300b-300x, are put into test mode by switching I/O switch 358 to provide the output from I/O driver 356 to the input of comparator circuit 366 and by closing comparator input switch 364 to provide the output from I/O receiver 354 to the other input of comparator circuit 366. Result switch 386 is opened.

Test circuits 350 in each of the slave components, such as slave components 300b-300x, are put into test result output mode by switching I/O switch 358 to provide the output from I/O driver 356 to I/O pin 352 and by opening comparator input switch 364. Result switch 386 is closed to provide the test result output signal to I/O driver 356 and I/O pin 352.

FIG. 12 is a diagram illustrating test circuit 350 in normal mode. In test system 302, memory component zero 300a is designated a master component and put into normal mode. Memory component zero 300a receives control signals via tester drivers 306 to put test circuit 350 into normal mode. I/O switch 358 is switched at 400 to provide the output from I/O driver 356 to I/O pin 352. Also, comparator input switch 364 is opened at 402 to reduce leakage current and result switch 386 is opened at 404.

In a write operation, I/O pin 352 receives input signals and I/O receiver 354 provides the input signals to the internal circuitry of memory component zero 300a. The input signals can be data signals that are written into memory component zero 300a as part of a test operation. Comparator input switch 364 is open and the input signals are not provided to comparator circuit 366.

In a read operation, I/O driver 356 receives internal data signals from the internal memory cells of memory component zero 300a. I/O driver 356 provides the received data signals to I/O pin 352. Also, as a master component, memory component zero 300a provides the received data signals via I/O driver 356 to one of the I/O pins 0-Y at 316 and slave memory components 300b-300x.

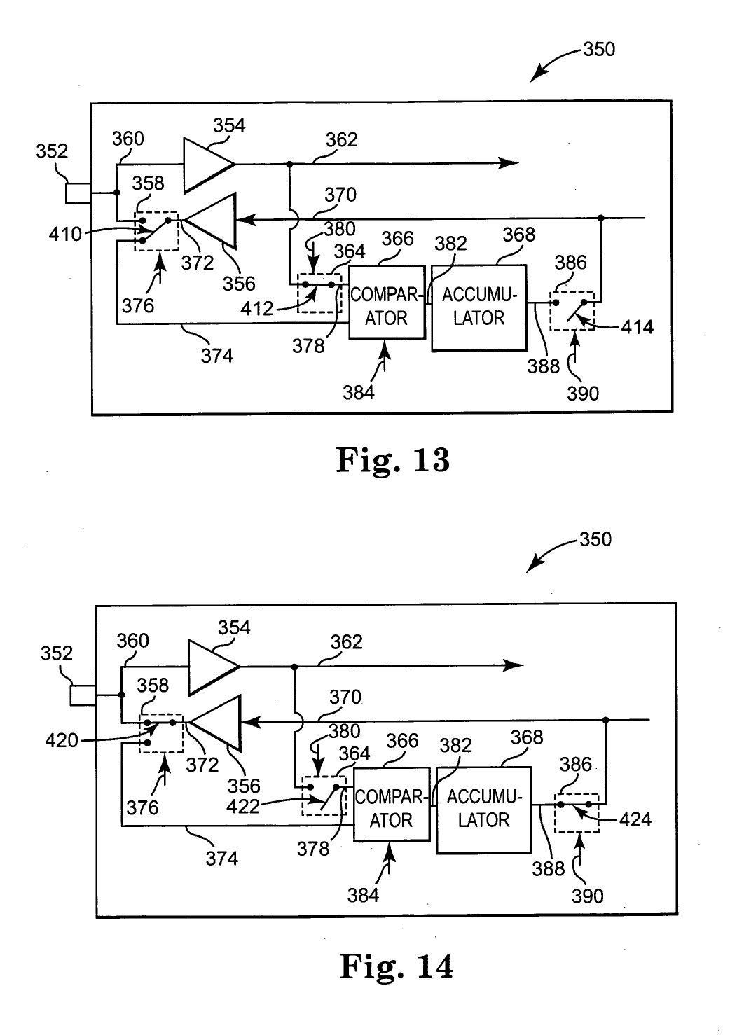

FIG. 13 is a diagram illustrating test circuit 350 in test mode. In test system 302, memory components 300b-300x are designated as slave components and put into test mode. Each of the memory components 300a-300x receives control signals via tester drivers 306 to put test circuits, such as test circuit 350, into test mode. I/O switch 358 is switched at 410 to provide the output from I/O driver 356 to the input of comparator circuit 366. Also, comparator input switch 364 is closed at 412 to provide the output from I/O receiver 354 to the other input of comparator circuit 366. In addition, result switch 386 is opened at 414.

In a write operation, I/O pin 352 receives input signals and I/O receiver 354 provides the input signals to the internal circuitry of the memory component 300b-300x that includes test circuit 350. The input signals can be data signals that are written into memory component 300b-300x as part of a test operation. Comparator input switch 364 is closed and the input signals are provided to comparator circuit 366, however, the comparison trigger at 384 is not activated to trigger a comparison via comparator circuit 366.

In a read operation, I/O driver 356 receives internal data signals from the internal memory cells of the memory component 300b-300x. I/O driver 356 provides the received data signals to the input of comparator circuit 366. Also, I/O pin 352 receives data output signals from master memory component zero 300a and I/O receiver 354 provides the received data output signals to the other input of comparator circuit 366 via comparator input switch 364. The comparison trigger at 384 is activated and comparator circuit 366 compares the inputs and provides a comparison test result to accumulator circuit 368. Test system 302 selects each of the slave memory components 300b-300x separately to read the test result from the selected slave memory component 300b-300x.

In one embodiment, accumulator circuit 368 is similar to accumulator 168 of FIG. 5. In one embodiment, if the comparison test results indicate a passing memory component, accumulator circuit 368 provides a low logic level output signal, and if any of the comparison test results indicate a failing memory component, accumulator circuit 368 provides a high logic level output signal.

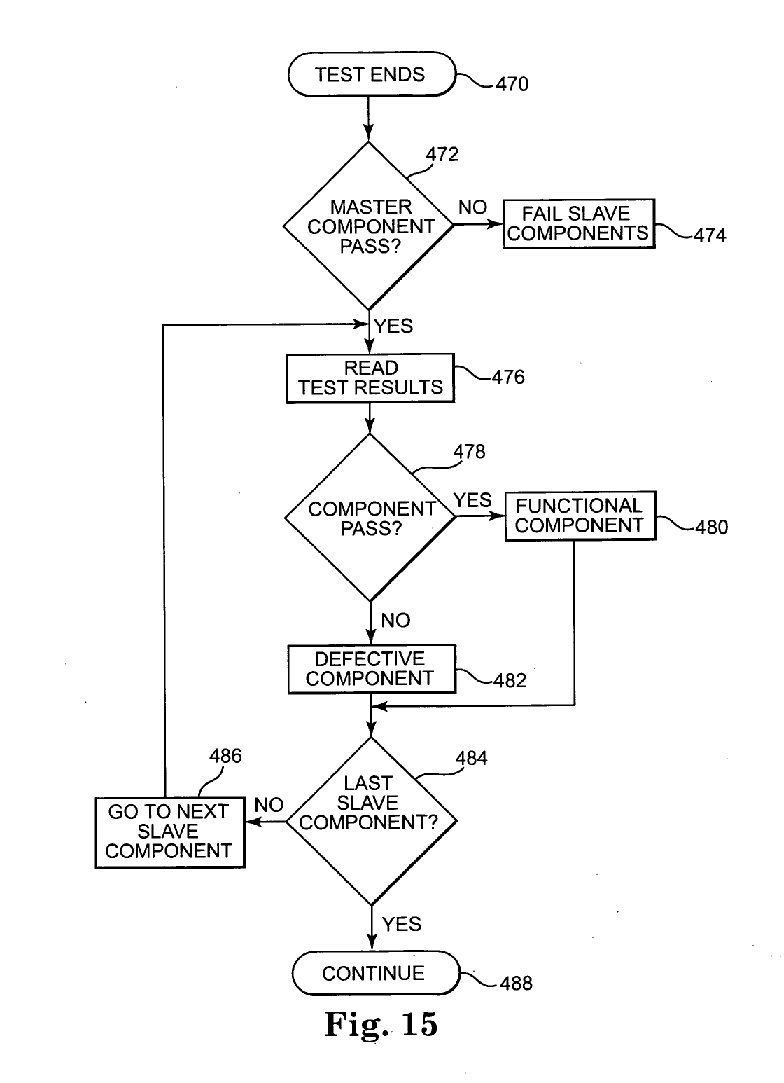

FIG. 14 is a diagram illustrating test circuit 350 in test result output mode. In test system 302, each of the slave memory components 300b-300x is selected via one of the chip select signals CS0-CSX and put into test result output mode to read the test result from the selected one of the slave memory components 300b-300x. Each of the memory components 300a-300x receives control signals via tester drivers 306 to put test circuits, such as test circuit 350, into the test result output mode. Result switch 386 is closed at 424 to provide the test result output signal from accumulator circuit 368 to the input of I/O driver 356. I/O switch 358 is switched at 420 to provide the output from I/O driver 356 to I/O pin 352, and comparator input switch 364 is opened at 422 to reduce leakage current. Test system 302 reads the test result from I/O pin 352.

In a write operation, I/O pin 352 receives input signals and I/O receiver 354 provides the input signals to the internal circuitry of the memory component 300b-300x. Comparator input switch 364 is open and the input signals are not provided to comparator circuit 366.

In a read operation, I/O driver 356 receives test results from accumulator circuit 368 via result switch 386. I/O driver 356 provides the received test results to I/O pin 352 and test system 302 reads the test results from the selected slave memory component 300b-300x.

FIG. 15 is a flowchart diagram illustrating an example of reading test results from memory components 300a-300x via test system 302. A test operation, such as a functional test operation, ends at 470. If master memory component zero 300a fails at 472, all of the slave memory components 300b-300x are failed at 474. The slave memory components 300b-300x can be retested using a different master component. If master memory component zero 300a passes at 472, test results are read from each of the slave memory components 300b-300x to obtain the pass/fail status of each of the slave memory components 300b-300x.

At 476, one of the slave memory components 300b-300x is selected and the other components, including master memory component 300a, are deselected. The selected one of the slave memory components 300b-300x is put into test result output mode and test results are read via test system 302. If the selected slave component passes at 478, i.e., if the selected slave component provides a passing logic level at I/O pin 352, the selected slave component is identified as a functional component at 480 via test system 302. If the selected slave component fails at 478, i.e. if the selected slave component provides a failing logic level at I/O pin 352, the selected slave component is identified as a defective component at 482 via test system 302.

If other slave memory components 300b-300x remain to be read at 484, test system 302 selects the next one of the slave memory components 300b-300x at 486 and the other memory components, including master memory component 300a, are deselected. The process repeats at 476. After the last of the slave memory components 300b-300x is identified as a functional or defective component, processing continues at 488.

Memory components 100/300 and test system 102/302 are configured to increase the number of memory components 100/300 that can be tested in parallel via test system 102/302. The number of memory components 100/300 tested in parallel is increased by reducing the number of test system driver/comparators used to test at least some of the memory components 100/300 via use of one or more test circuits 150/350.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed:

1. An integrated circuit, comprising:
an input/output pad configured to receive first output signals of another integrated circuit that are based on input signals;
an internal circuit configured to receive the input signals and provide second output signals based on the input signals;
a test circuit configured to receive the first output signals and the second output signals, wherein the test circuit comprises:
a comparator configured to compare the first output signals and the second output signals and provide comparison results;
a first switch configured to route the second output signals to one of an input of the comparator and the input/output pad; and
a second switch configured to route the first output signals to another input of the comparator.

2. The integrated circuit of claim 1, comprising:
a test mode control circuit configured to put the test circuit into one of a normal mode and a test mode, wherein the test mode control circuit controls the first switch to route the second output signals to the input of the comparator and the second switch to route the first output signals to the other input of the comparator in test mode and the test mode control circuit controls the first switch to route the second output signals to the input/output pad and the second switch to open in the normal mode.

3. The integrated circuit of claim 1, wherein the test circuit comprises:
an accumulator configured to receive the comparison results and provide an accumulator output signal that indicates if a mismatch occurred between the first output signals and the second output signals.

4. The integrated circuit of claim 3, wherein the test circuit comprises:
a third switch, wherein the accumulator is configured to control the third switch based on the accumulator output signal.

5. The integrated circuit of claim 3, wherein the test circuit comprises:
a third switch configured to route the accumulator output signal to the first switch that is configured to route the accumulator output signal to the input/output pad to read the accumulator output signal.

6. A random access memory test system, comprising:
driver circuits configured to provide inputs to a master random access memory and a slave random access memory;
input/output circuits configured to provide first data signals to the master random access memory and the slave random access memory and to receive second data signals from the master random access memory, wherein the inputs put the master random access memory into normal mode and the slave random access memory into test mode;
wherein the master random access memory comprises:
a master switch controlled to route the second data signals to the input/output circuits and to the slave random access memory; and
wherein the slave random access memory comprises:
a slave comparator configured to compare the second data signals and third data signals provided via the slave random access memory and provide comparison results;
a first switch controlled to route the third data signals to an input of the slave comparator; and
a second switch controlled to route the second data signals to another input of the comparator.

7. The random access memory test system of claim 6, comprising:
a tester control circuit configured to compare the first data signals to the second data signals and provide a test result.

8. The random access memory test system of claim 6, wherein the slave random access memory comprises:
an accumulator configured to receive the comparison results and provide an accumulator output signal that indicates if a mismatch occurred between the second data signals and the third data signals.

9. The random access memory test system of claim 8, comprising a tester control circuit, wherein the slave random access memory comprises a third switch controlled via the accumulator output signal and the tester control circuit is configured to provide a test that determines the state of the third switch.

10. The random access memory test system of claim 8, comprising a tester control circuit, wherein the slave random access memory comprises a third switch configured to route the accumulator output signal to the first switch that is configured to route the accumulator output signal to the input/output circuits and the tester control circuit is configured to read the accumulator output signal.

11. The random access memory test system of claim 6, wherein the master random access memory is a master dynamic random access memory and the slave random access memory is a slave dynamic random access memory.

12. A random access memory, comprising:
means for receiving first output signals of another random access memory, which are based on input signals;
means for providing second output signals that are based on the input signals;
means for testing the second output signals, comprising:
means for comparing the first output signals and the second output signals to provide comparison results;
means for routing the first output signals to the means for comparing; and
means for routing the second output signals to one of the means for comparing and the means for receiving.

13. The random access memory of claim 12, comprising:
means for controlling the means for testing to put the means for testing into one of a normal mode and a test mode.

14. The random access memory of claim 13, wherein the means for controlling controls the means for routing the second output signals to route the second output signals to the means for comparing and controls the means for routing the first output signals to route the first output signals to the means for comparing in the test mode, and the means for controlling controls the means for routing the second output signals to route the second output signals to the means for receiving in the normal mode.

15. The random access memory of claim 12, wherein the means for testing comprises:
means for accumulating the comparison results to provide an accumulator output signal that indicates if a mismatch occurred between the first output signals and the second output signals.

16. The random access memory of claim 15, wherein the means for testing comprises:
means for switching that is controlled by the accumulator output signal.

17. The random access memory of claim 15, wherein the means for testing comprises:
means for routing the accumulator output signal to the means for routing the second output signals to route the accumulator output signal to the means for receiving to read the accumulator output signal.

18. A method for testing an integrated circuit, comprising:
receiving at an input/output pad of the integrated circuit first output signals of another integrated circuit, which are based on input signals;
providing second output signals from the integrated circuit, which are based on the input signals;
routing the first output signals to a comparator circuit of the integrated circuit;
routing the second output signals to one of the comparator circuit and the input/output pad; and
comparing the first output signals and the second output signals to provide comparison results via the comparator circuit.

19. The method of claim 18, comprising:
putting the integrated circuit into one of a normal mode and a test mode;
routing the first output signals and the second output signals to the comparator circuit in the test mode; and
routing the second output signals to the input/output pad in the normal mode.

20. The method of claim 18, comprising:
accumulating the comparison results at an accumulator circuit of the integrated circuit to provide an accumulator output signal that indicates if a mismatch occurred between the first output signals and the second output signals.

21. The method of claim 20, comprising:
switching a switch of the integrated circuit based on the accumulator output signal.

22. The method of claim 20, comprising:
routing the accumulator output signal to the input/output pad to read the accumulator output signal.

23. A method for testing random access memories, comprising:
driving inputs to a master random access memory and a slave random access memory;
driving first data signals to the master random access memory and the slave random access memory;
routing second data signals from the master random access memory to the slave random access memory via a master switch in the master random access memory;
routing third data signals from the slave random access memory to an input of a slave comparator in the slave random access memory via a first slave switch in the slave random access memory;
routing the second data signals to another input of the slave comparator via a second slave switch in the slave random access memory; and
comparing the second data signals and the third data signals via the slave comparator to provide comparison results.

24. The method of claim 23, comprising:
comparing the first data signals and the second data signals to provide a test result via a tester control circuit.

25. The method of claim 23, comprising:
accumulating the comparison results via an accumulator in the slave random access memory to provide an accumulator output signal that indicates if a mismatch occurred between the second data signals and the third data signals.

26. The method of claim 25, comprising:
routing the accumulator output signal to control a third slave switch in the slave random access memory; and
testing the state of the third slave switch via a tester control circuit.

27. The method of claim 25, comprising:
routing the accumulator output signal to the first slave switch via a third slave switch in the slave random access memory;
routing the accumulator output signal from the first slave switch to a tester control circuit; and
reading the accumulator output signal via the tester control circuit.
